(19) United States
(12) Patent Application Publication
(10) Pub. No.: US 2017/0191155 A1
(43) Pub. Date: Jul. 6, 2017

(54) VAPOR DISPOSITION SYSTEM

(71) Applicant: BOE TECHNOLOGY GROUP CO., LTD., Beijing (CN)

(72) Inventors: Changqi Hu, Beijing (CN); Shupeng Guo, Beijing (CN); Qinghua Zou, Beijing (CN); Bin Bu, Beijing (CN)

(21) Appl. No.: 15/218,507

(22) Filed: Jul. 25, 2016

(30) Foreign Application Priority Data
Jan. 4, 2016 (CN) 201610006738.8

(51) Int. Cl. C23C 14/50; C23C 14/24

(52) U.S. Cl. CPC C23C 14/50; C23C 14/24

(57) ABSTRACT

A vapor deposition system including a vapor deposition mechanism and a separation mechanism is provided. The vapor deposition mechanism includes a vapor deposition source, and further includes a vapor deposition baseplate and a cover plate that are located at a side of the vapor deposition source in a vapor deposition direction in order; the cover plate comprises a frame defining an enclosed frame region, the frame comprises a contact surface with the vapor deposition baseplate, and the contact surface comprise an adhesion portion, and the vapor deposition baseplate is capable of being adhered to the cover plate; the separation mechanism comprises at least one support plate and at least one movable bar connected with the support plate, the movable bar is configured to separate the vapor deposition baseplate from the cover plate after completion of film vapor deposition.

### TECHNICAL FIELD

Embodiments of the present disclosure pertain to a vapor deposition system.

### BACKGROUND

Vacuum vapor deposition method is such a method in which a thin film forming raw material contained within a container is heated and evaporated in a vacuum chamber so that atoms or molecules of the material are vaporized and escape from the surface of the material, thus producing vapor stream, and the vapor steam is incident onto the surface of a substrate and then condenses to from a solid film on the substrate. Vacuum vapor deposition method has been widely used in the process of manufacturing display devices. For example, an organic light-emitting diode (OLED) display panel comprises a cathode, an anode and a luminescent material layer located between the cathode and the anode, and the cathode and the anode are generally formed by way of vacuum vapor deposition method.

### SUMMARY

An embodiment of the present disclosure provided a vapor deposition system, comprising a vapor deposition mechanism and a separation mechanism. The vapor deposition mechanism comprises a vapor deposition source, and further comprises a vapor deposition baseplate and a cover plate that are located at a side of the vapor deposition source in a vapor deposition direction in order, and the vapor deposition mechanism is configured for depositing a thin film on a first surface of the vapor deposition baseplate; the cover plate comprises a frame defining an enclosed frame region, the frame comprises a contact surface with the vapor deposition baseplate, and the contact surface comprise an adhesion portion, and the vapor deposition baseplate is capable of being adhered to the cover plate; the separation mechanism comprises at least one support plate and at least one movable bar connected with the support plate, the movable bar is configured to separate the vapor deposition baseplate from the cover plate after completion of film vapor deposition, the support plate comprises a third surface and a fourth surface that are opposite to each other, the third surface of the support plate is capable of being in contact with a second surface of the vapor deposition baseplate in the frame region, and the second surface is opposite to the first surface; the movable bar is connected to the fourth surface of the support plate and is configured to bring the support plate to move in a vertical direction to the frame region, and an area of the third surface is greater than a contact area between the movable bar and the support plate.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1 is a schematic view showing a vacuum vapor deposition process;

FIG. 2 is a schematic view showing film vapor deposition conducted upon a vapor deposition baseplate provided by an embodiment of the present disclosure;

FIG. 3 is a schematic view showing a process of separating the vapor deposition baseplate from a cover plate provided by the embodiment of the present disclosure;

FIG. 4 is a schematic view of another cover plate provided by an embodiment of the present disclosure;

FIG. 5 is a schematic view of still another cover plate provided by an embodiment of the present disclosure;

FIG. 6 is a schematic view showing another process of separating the vapor deposition baseplate from the cover plate provided by an embodiment of the present disclosure;

FIG. 7 is a schematic sectional view of a separation mechanism provided by an embodiment of the present disclosure;

FIG. 8 is a schematic sectional view of another separation mechanism provided by an embodiment of the present disclosure; and

FIG. 9 is a schematic view showing another modification of the embodiment of the present disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present application for disclosure, are not intended to indicate any sequence, amount or importance, but distinguish various components. Also, the terms such as “a,” “an,” etc., are not intended to limit the amount, but indicate the existence of at least one. The terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “right,” “left” and the like are only used to indicate relative position relationship, and when the position of the object which is described is changed, the relative position relationship may be changed accordingly.

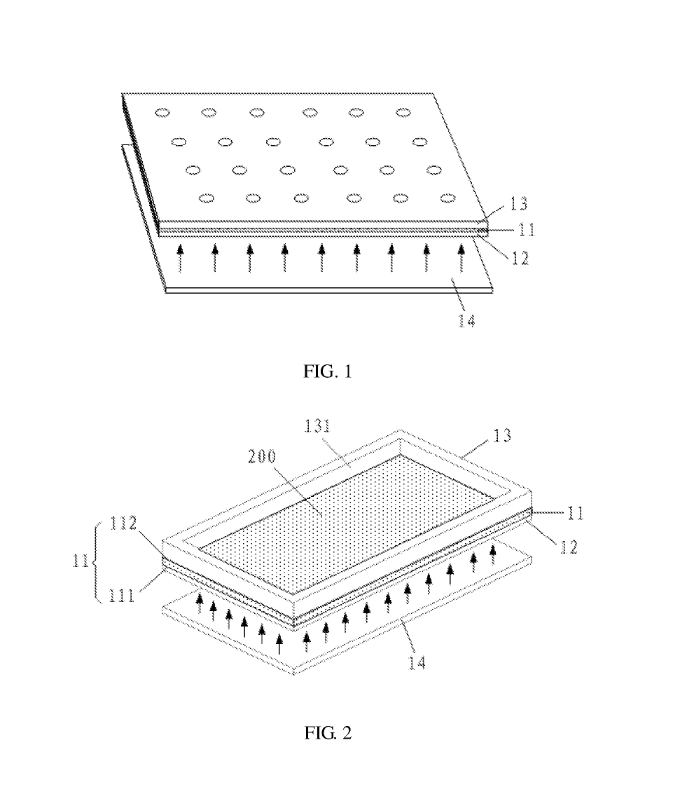

As shown in FIG. 1, a vapor deposition baseplate 11 is placed in alignment with a mask plate 12; the vapor deposition baseplate 11 is positioned above the mask plate 12, and an evaporator source 14 is placed below the mask plate 12. Due to potential relative movement between the vapor deposition baseplate 11 and the mask plate 12 in the process of the vacuum vapor deposition, the area for film formation is likely to shift, which causes poor accuracy of the formed film, and therefore, as shown in FIG. 1, a cover plate 13 is placed onto the upper side of the vapor deposition baseplate 11, and the cover plate 13 is adhered together with the substrate plate 11 through glue or the like to avoid the shift of the baseplate 11. As shown in FIG. 1, the cover plate 13 is formed with a plurality of through holes thereon, and after the vapor deposition onto the substrate plate 11 is finished, a movable bar is moved to pass through at least one of the through holes to push the vapor deposition baseplate 11 outwards, so that the vapor deposition baseplate 11 can be separated from the cover plate 13. However, due to the through holes in the cover plate 13 being small, the movable bar is in contact with the vapor deposition baseplate 11 and the contact area is dot-like, and therefore, this method is also referred to as dot-like separation. Dot-like separation may cause uneven stress upon the surface of the vapor deposition baseplate 11 and in turn cause operation fault of the baseplate or the like.

An embodiment of the present disclosure provides a vapor deposition system comprising a vapor deposition mechanism and a separation mechanism.

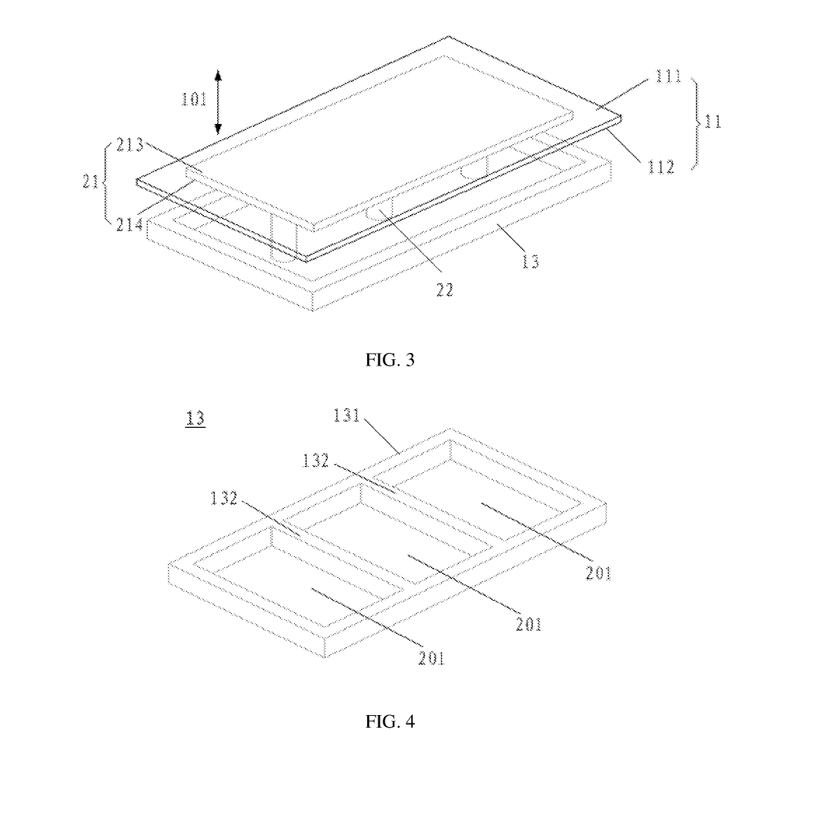

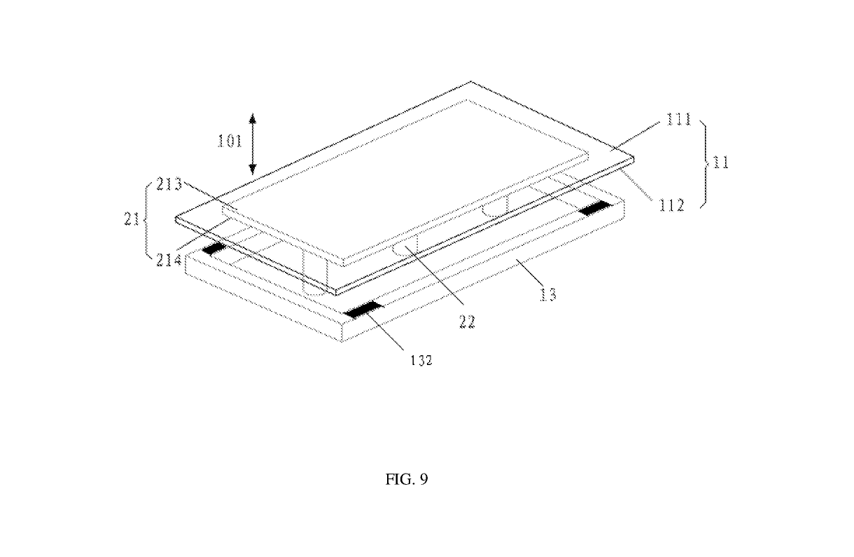

As shown in FIG. 2, the vapor deposition mechanism is configured for vapor-depositing a thin film onto a first surface 111 of a vapor deposition baseplate 11. The vapor deposition mechanism comprises a vapor deposition source 14 and comprises a vapor deposition baseplate 11 and a cover plate 13 which are located at a side of the vapor deposition source 14 in the vapor deposition direction thereof in order; the cover plate 13 comprises a frame 131 defining an enclosed frame region 200, the frame 131 has a contact surface with the vapor deposition baseplate 11, and the contact surface is provided with an adhesion portion, so that the vapor deposition baseplate 11 and the cover plate 13 can be adhered to each other, that is, held together by adhesion. In one example, the adhesion portion can be provided over the whole upper surface of the frame 131 (with reference to FIG. 3), or on part of the upper surface of the frame; for example, with reference to FIG. 9, the adhesion portions 132 are provided on the corners of the frame 131.

In one example, the vapor deposition source 14 may be provided thereon with a corresponding raw material to be vapor-deposited as required, and the vapor deposition baseplate 11 may be provided, as required, with a substrate fixed thereon to be formed with a thin film.

To be specified, in order to create a specific thin film pattern at a position on the vapor deposition baseplate 11, as shown in FIG. 2, it is generally further provided with a mask plate 12 between the vapor deposition source 14 and the vapor deposition baseplate 11. Because the mass of the cover plate 13 generally is relatively greater, the vapor deposition baseplate 11 and the cover plate 13 are adhered together and cover the upper side of the mask plate 12, and this configuration is favorable in preventing the vapor deposition baseplate 11 and the mask plate 12 from relative movement.

As shown in FIG. 3, a separation mechanism is provided and configured for separating the vapor deposition baseplate 11 from the cover plate 13 after the completion of the film vapor deposition, and the separation mechanism comprises at least one support plate 21 and at least one movable bar 22 connected with the support plate 21. FIG. 3 illustrates one support plate 21 connected with three movable bars 22 as an example, but the embodiments of the present disclosure are not limited to such a combination. As shown in FIG. 3, the support plate 21 comprises a third surface 213 and a fourth surface 214 that are opposite to each other, and the third surface 213 of the support plate 21 is provided in contact with the second surface 112 of the vapor deposition baseplate 11 in the frame region 200, and the second surface 112 is opposite to the first surface 111. That is to say, the separation mechanism is operated to overturn the vapor deposition baseplate 11 and cover plate 13 adhered together in the vapor deposition mechanism by 180°, i.e., in the vapor deposition mechanism, the first surface 111 of the vapor deposition baseplate 11 is below the second surface 112, so as to perform vapor deposition on the first surface 111 to from a thin film. In the separation mechanism, the second surface 112 of the vapor deposition baseplate 11 is located below the first surface 111, so that the third surface 213 of the support plate 21 contacts with the second surface 112 of the vapor deposition baseplate 11 to avoid damage to the formed film. Please note that FIG. 2 and FIG. 3 are views viewed from opposite positions in the vertical direction 101.

The movable bars 22 are connected to the fourth surface 214 of the support plate 21 in order to drive the support plate 21 to move in the vertical direction (i.e., the direction 101 as indicated in FIG. 3) in the frame region 200, and the area of the third surface 213 is greater than the contact area between the movable bar 22 and the support plate 21.

In the embodiment of the present disclosure, the movable bars 22 contact with the fourth surface of the support plate 21 and thus are connected to the fourth surface 214 of the support plate 21 respectively, and the contact area between the movable bars 22 and the support plate 21 is less than the area of the third surface 213, and further the third surface 213 contacts with the second surface 112 of the vapor deposition baseplate 11 in the frame region 200, thus, in the embodiment of the present disclosure, the contact area between the movable bars 22 and the fourth surface of the support plate 21 is less than the contact area between the third surface 213 and the second surface 112 of the vapor deposition baseplate 11 in the frame region 200. Because the contact area between the support plate 21 and the vapor deposition baseplate 11 is relatively greater, the support force upon the vapor deposition baseplate 11 by the movable bars 22 is relatively even, and can effectively depress or eliminate the operation fault, compared with the case in which the movable bar passes through the via hole and directly contacts with the vapor deposition baseplate and push outwards the vapor deposition baseplate.

In the vapor deposition system provided by the embodiment of the present disclosure, the cover plate and the vapor deposition baseplate of the vapor deposition mechanism are adhered together, and the cover plate and the vapor deposition baseplate are separated from each other after the completion of the vapor deposition. The cover plate in the embodiment of the present disclosure defines an enclosed frame region, and the support plate of the separation mechanism contacts with the vapor deposition baseplate in the frame region so that the deposition baseplate can move upward from the frame region and thus is separated from the cover plate. In the embodiment of the present disclosure, due to the fact that the support plate and the vapor deposition baseplate contact with each other in a surface-contact manner, the operation fault and the related problem due to the uneven stress caused to the vapor deposition baseplate can be avoided.

In consideration of a vapor deposition baseplate of a greater dimension, its central area may fall due to the gravity force when the vapor deposition baseplate is adhered to the cover plate as shown in FIG. 2, and in this case the surface of the vapor deposition baseplate is not a flat plane any more and may cause the deposited film to have an uneven thickness.

In another example of the embodiment of the present disclosure, as shown in FIG. 4, the cover plate 13 further comprises at least one connecting rod 132 located in the frame region 200, the connecting rod 132 is connected with the frame 131 and divides the frame region 200 into at least two sub-frame regions 201. FIG. 4 illustrates an example in which the cover plate 13 comprises two connecting rods 132, and the two connecting rods 132 divide the frame region 200 (e.g., as shown in FIG. 2) into three sub-frame regions 201.

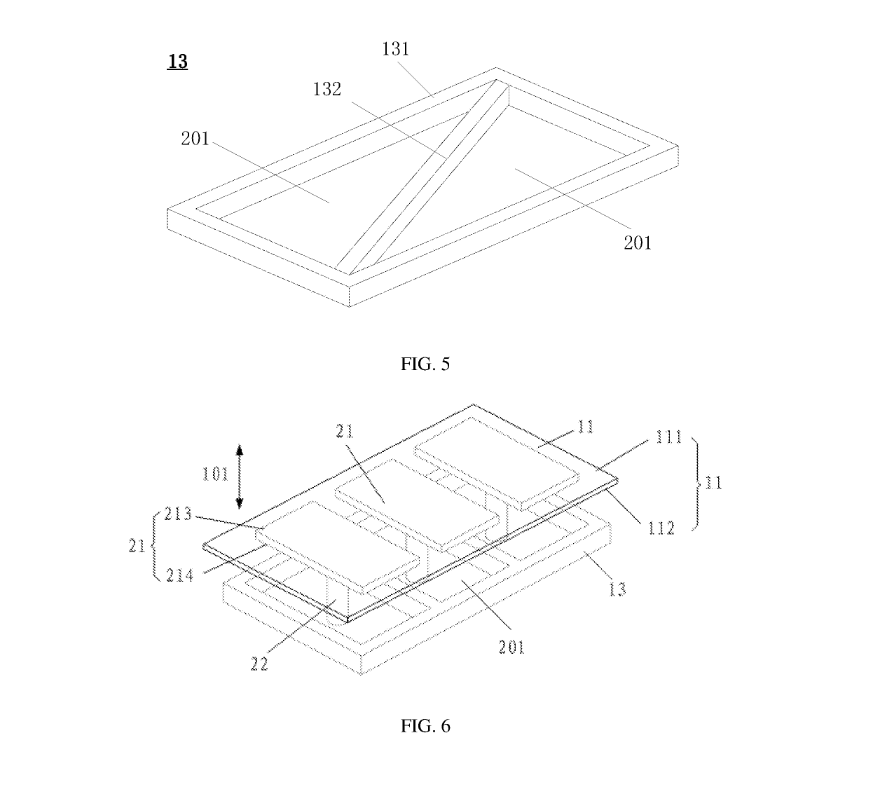

Of course, the location and manner for providing the connecting rod(s) 132 are not restricted to that as shown in FIG. 4. For example, as shown in FIG. 5, the connecting rod 132 is provided at the position along a diagonal line of the frame region 200 so as to divide the frame region 200 into two sub-frame regions 201.

For example, the at least two sub-frame regions are identical to each other in their areas. It is also possible that, as shown in FIG. 4, the two connecting rods 132 divide the frame region 200 into three sub-frame regions 201 having their areas equal to one another. In this way, the support force of the cover plate 13 upon the vapor deposition baseplate 11 can be distributed more evenly, thus improving the thickness consistency of the deposited film on the vapor deposition baseplate.

As shown in FIG. 6, the separation mechanism comprises support plates that are in one-to-one correspondence with the sub-frame regions 201, the third surface of each support plate 21 contacts with the second surface 112 of the vapor deposition baseplate 11 in the corresponding sub-frame region 201 to the support plate 21. As shown in FIG. 6, each of the three sub-frame region 201 corresponds to one support plate 21, and each support plate 21 is connected with one movable bar 22.

In this case, the connecting rods 132 divide the frame region 200 into three sub-frame regions 201, and the separation mechanism provides one support plate 21 in each of the sub-frame regions 201 respectively, and each of the support plates 21 is connected with one movable bar 22, so that the vapor deposition baseplate 11 in each of the sub-frame regions 201 can be separated from the cover plate 13 by means of one support plate 21.

The contact area between the support plate and the vapor deposition baseplate can be designed as great as possible while being less than the area of the sub-frame region in which the support plate is located, so as to further improve the contact area between the support plate and the vapor deposition baseplate. For example, the area of the third surface 213 of the support plate 21 is greater than half of the area of the sub-frame region 201.

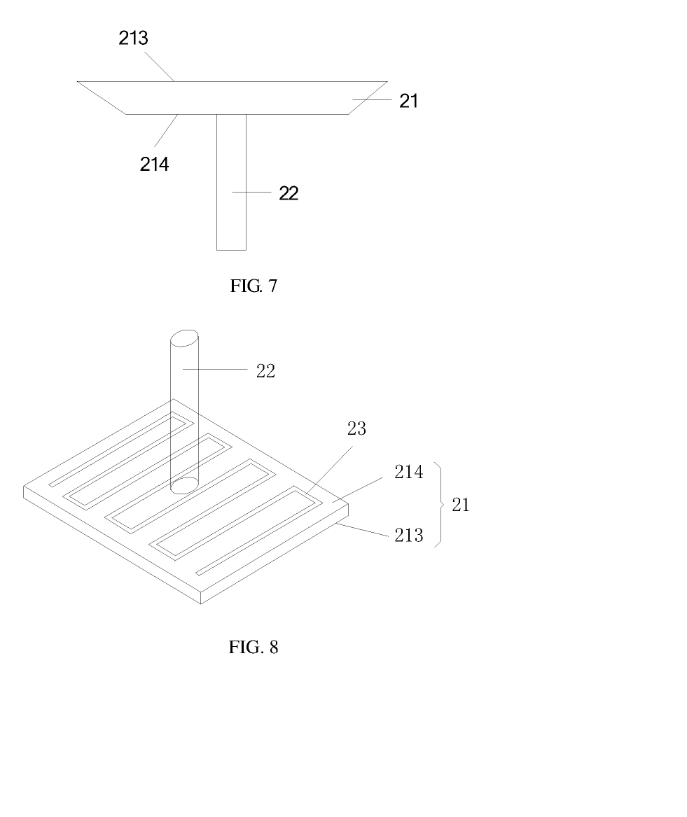

It should be understood, as shown in FIGS. 3 and 6, the third surface 213 of the support plate 21 has an area equal to that of the fourth surface 214. On the other hand, the support plate 21 of the embodiment of the present disclosure may also be in the design as shown in FIG. 7, in which the third surface 213 and the fourth surface 214 are equal to each other in areas. While in the embodiment of the present disclosure, it is preferable that the contact area between the support plate 21 and the vapor deposition baseplate 11 can be designed as great as possible, then the area of the third surface 213 of the support plate 21 is greater than or equal to the area of the fourth surface 214.

For example, the vapor deposition baseplate can be used to form a display panel masterboard, and can be divided into a plurality of display panel units (e.g., at least two display panel units), these panel units are arranged side by side, and the sub-frame regions are in one-to-one correspondence with the display panel units. The display panel masterboard will finally cut to produce independent display panel units. Due to the fact that, at the position of a connecting rod, the support plate 21 cannot contact with the vapor deposition baseplate 11, thus the vapor deposition baseplate is subjected to a force at the position corresponding to the connecting rod different from the force at the position in the frame region. When the sub-frame regions are in one-to-one correspondence with the display panel units, each of the display panel units can receive even stress, thus alleviating or reducing display problems occurred to the display panel units due to uneven force.

For example, the vapor deposition system may further comprise a cooling component; and the cooling component is used to reduce the temperature of the vapor deposition baseplate. Because, in the vapor deposition process, the raw material to be vapor-deposited will be ionized first and then sprayed onto the vapor deposition baseplate, thus the deposited film will be at a high temperature (e.g., hundreds centigrade) in the deposition chamber, and the formed film and the vapor deposition baseplate is likely to deform under such a high temperature. If the temperature of the vapor deposition baseplate is reduced after a cooling period, the temperature of the film deposited on the vapor deposition baseplate is reduced accordingly, and the cooled film is less likely to deform.

For example, as shown in FIG. 8, the cooling component comprises a cooling tube 23 within which the gas and/or liquid can flow to carry heat out, and the cooling tube 23 is provided on a surface of the support plate 21 having no contact with the vapor deposition baseplate. For example, as shown in FIG. 7, the cooling tube 23 is provided on the fourth surface 214 of the support plate 21. That is to say, the temperature of the support plate is reduced by using low-temperature gas and/or liquid running through the cooling tube, the temperature of the vapor deposition baseplate can be reduced when the support plate contacts with the vapor deposition baseplate.

For example, as shown in FIG. 8, the cooling tube 23 is provided on the support plate 21 in a zigzag arrangement. The zigzag arrangement for the cooling tube 23 can further enlarge the contact area between the cooling tube 23 and the support plate 21, thereby reducing the temperature of the support plate 21 even more rapidly. Beside this example of cooling tube, the cooling component can also take other forms, for example, cooling fins, a thermotube, or thermoelectric cooling component, or the like.

For example, the support plate is a metal baseplate or a ceramic baseplate (for example, an aluminum nitride baseplate). The thermal conductivity of a metal material or a ceramic material is greater than that of a plastic material and the like, which further facilitates heat transfer and compensation, thus reducing the temperature of the support plate even more quickly.

What are described above is related to the illustrative embodiments of the disclosure only and not limitative to the scope of the disclosure; the scopes of the disclosure are defined by the accompanying claims.

The present application claims the priority of the Chinese Patent Application No. 201610006738.8 filed on Jan. 4, 2016, which is incorporated herein by reference as part of the disclosure of the present application.

What is claimed is:

1. A vapor deposition system, comprising a vapor deposition mechanism and a separation mechanism,
wherein the vapor deposition mechanism comprises a vapor deposition source, and further comprises a vapor deposition baseplate and a cover plate that are located at a side of the vapor deposition source in a vapor deposition direction in order, and the vapor deposition mechanism is configured for depositing a thin film on a first surface of the vapor deposition baseplate;
the cover plate comprises a frame defining an enclosed frame region, the frame comprises a contact surface with the vapor deposition baseplate, and the contact surface comprise an adhesion portion, and the vapor deposition baseplate is capable of being adhered to the cover plate;
the separation mechanism comprises at least one support plate and at least one movable bar connected with the support plate, the movable bar is configured to separate the vapor deposition baseplate from the cover plate after completion of film vapor deposition,
the support plate comprises a third surface and a fourth surface that are opposite to each other, the third surface of the support plate is capable of being in contact with a second surface of the vapor deposition baseplate in the frame region, and the second surface is opposite to the first surface;
the movable bar is connected to the fourth surface of the support plate and is configured to bring the support plate to move in a vertical direction to the frame region, and an area of the third surface is greater than a contact area between the movable bar and the support plate.

2. The vapor deposition system according to claim 1, wherein the cover plate further comprises at least one connecting rod located in the frame region,
the connecting rod is connected with the frame and divides the frame region into at least two sub-frame regions;
the separation mechanism comprises at least two support plates each corresponding to one sub-frame region, the third surface of each of the support plates is in contact with the second surface of the vapor deposition baseplate in a sub-frame region corresponding to this support plate.

3. The vapor deposition system according to claim 2, wherein the at least two sub-frame regions are identical to each other in area.

4. The vapor deposition system according to claim 2, wherein the third surface of each support plate has an area greater than half of an area of the sub-frame region corresponding to this area.

5. The vapor deposition system according to claim 2, wherein the vapor deposition baseplate is configured to form a display panel masterboard, and is divided into a plurality of display panel units, and the sub-frame regions are in one-to-one correspondence with the display panel units.

6. The vapor deposition system according to claim 3, wherein the vapor deposition baseplate is configured to form the display panel masterboard, and is divided into several display panel units, and the sub-frame regions are in one-to-one correspondence with the display panel units.

7. The vapor deposition system according to claim 1, wherein the vapor deposition system further comprises a cooling component; and the cooling component is configured to reduce a temperature of the vapor deposition baseplate.

8. The vapor deposition system according to claim 7, wherein the cooling component comprises a cooling tube which allows gas and/or liquid to flow therein, and the cooling tube is provided on a surface of the support plate having no contact with the vapor deposition baseplate.

9. The vapor deposition system according to claim 8, wherein the cooling tube is provided on the fourth surface of the support plate.

10. The vapor deposition system according to claim 8, wherein the cooling tube is provided on the surface of the support plate in a zigzag arrangement.

11. The vapor deposition system according to claim 9, wherein the cooling tube is provided on the surface of the support plate in a zigzag arrangement.

12. The vapor deposition system according to claim 1, wherein the support plate is a metal plate or a ceramic baseplate.

13. The vapor deposition system according to claim 3, wherein the vapor deposition baseplate is configured to form a display panel masterboard, and is divided into a plurality of display panel units, and the sub-frame regions are in one-to-one correspondence with the display panel units.
